(19) United States
(12) Patent Application Publication
(10) Pub. No.: US 2006/0251912 A1
(43) Pub. Date: Nov. 9, 2006

(54) MoSi2-Si3N4 composite coating and manufacturing method thereof

(75) Inventors: Jae Soo Kim, Seoul (KR); Kyeung Ho Kim, Seoul (KR); Ji Young Byun, Seoul (KR); Jin Kook Yoon, Seoul (KR); Doo Yong Kim, Seoul (KR); Jong Kown Lee, Suwon (KR); Jong Chul Shin, Seoul (KR); Dae Ho Rho, Jeonju (KR)

Correspondence Address: MORRISON & FOERSTER LLP, 1650 TYSONS BOULEVARD, SUITE 300, MCLEAN, VA, 22102, US

(73) Assignee: Korea Institute of Science and Technology, Seoul (KR)

(21) Appl. No.: 11/482,840

(22) Filed: Jul. 10, 2006

Related U.S. Application Data
(62) Division of application No. 10/337,367, filed on Jan. 7, 2003.

(30) Foreign Application Priority Data
Mar. 14, 2002 (KR) 2002/13914

(51) Int. Cl. C23C 16/00; B32B 15/04

(52) U.S. Cl. 428/457; 427/248.1; 428/698

(57) ABSTRACT

A MoSi₂—Si₃N₄ composite coating which is coated on a surface of base materials which are molybden, molybden alloy, molybden-coated niobium or molybden-coated niobium alloy and a manufacturing method thereof. The MoSi₂—Si₃N₄ composite coating on the surface of the base material can be formed by forming a Mo₂N diffusion layer by vapor-depositing of nitrogen on the surface of the base material and forming a MoSi₂—Si₃N₄ composite coating by vapor-depositing of silicon on the surface of the Mo₂N diffusion layer, or the MoSi₂—Si₃N₄ composite coating on the surface of the base material can be formed by forming a MoSi₂ diffusion layer by vapor-depositing of silicon on a surface of a base material by the CVD method, transforming the MoSi₂ diffusion layer into a Mo₅Si₃ diffusion layer by heating under a high-purity hydrogen or argon atmosphere, forming a Mo₂N—Si₃N₄ composite diffusion layer by vapor-depositing of nitrogen on the surface of the Mo₅Si₃ diffusion layer by the CVD method and forming a MoSi₂—Si₃N₄ composite coating by vapor-depositing of silicon on the surface of the Mo₂N—Si₃N₄ composite diffusion layer. The MoSi₂—Si₃N₄ composite coating manufactured by the above method is characterized as a structure in which Si₃N₄ particles are distributed in a MoSi₂ grain boundary of equiaxed grains, thus to improve cyclic oxidation resistance of the base material, improve low-temperature oxidation resistance, and improve mechanical properties of the coating. Therefore, transmission of fine cracks by the thermal stress can be restrained.

### BACKGROUND OF THE INVENTION

1. Field of the Invention

The present invention relates to a coating having excellent oxidation resistance and corrosion resistance, which is provided on the surface of metals such as molybdenum, niobium and their alloys, and manufacturing method thereof.

2. Description of the Background Art

Due to properties of low vapor pressure and thermal expansion coefficient, Molybdenum(Mo) having a melting point of 2617° C. maintains high strength and hardness at a high temperature, and has better high-temperature mechanical, thermal properties than any other metal. Accordingly, it is a core material which can be applied to fields of aerospace, atomic energy and the like.

However, the material has a disadvantage that it can be used only in a non-oxidizing condition since it forms volatile MoO₃ by reacting with oxygen at a low temperature of about 600° C.

On the other hand, since niobium (Nb) has a melting point of 2467° C., a density lower than that of molybdenum (Nb; 8.55 g/cm³, Mo; 10.2 g/cm³), and its high-temperature mechanical property is excellent as that of molybdenum, niobium or niobium alloys can be advantageously used as next-generation high-temperature structural materials. However, these materials also do not show high-temperature oxidation resistance.

To improve oxidation resistance of molybdenum or molybdenum alloys, methods such as surface coating treatment, by which MoSi₂ having an excellent oxidation resistance is coated on a molybdenum surface, have been widely used. In case of niobium or niobium alloys, to improve oxidation resistance, a surface coating treatment, which is similar to that for molybdenum and is performed after depositing molybdenum on the surface in a predetermined thickness, has been being studied.

In case of a slurry surfacing method among the surface coating treatments, the formation of an alloy coating can be easily performed, but a amount of defects, such as pore and the like can be formed.

In case of directly coating a MoSi₂ layer using a low-pressure plasma spraying method, the formation of the alloy coating is easily performed, but it is difficult to adjust the composition and to form MoSi₂ coating without a defect.

Therefore, reactive-diffusion methods such as pack-siliconizing, CVD, dipping of liquid silicon and the like are generally adopted as a coating treatment. The pack-siliconizing method and CVD method, in which the silicon diffuse under the condition of gas state and are deposited on the surface of the basic materials, are distinguished from the dipping method in which the silicon diffuse under the liquid condition.

Since a dense silicon dioxide (SiO₂) layer is formed on the surface of MoSi₂ layer and restrains movement of oxygen when the MoSi₂ layer coated on molybdenum or niobium is exposed to a high-temperature oxidation atmosphere, internal base materials can be protected.

However, thermal, mechanical limitation which are problematic for commercialization of MoSi₂coating is affected by following three factors.
(1) interdiffusion between molybdenum or niobium and MoSi₂ coating,
(2) thermal stress generated by a difference of thermal expansion coefficients between molybdenum (5.1×10⁻⁶/° C.) or niobium (7.2×10⁻⁶/° C.) and MoSi₂ coating (9.5×10⁻⁶/° C.), or between a difference of thermal expansion coefficients between MoSi₂ coating and SiO₂ layer (0.5×10⁻⁶/° C.), and
(3) pest oxidation that the MoSi₂ coating is divided into MoO₃ and SiO₂, which is due to the rapid oxidation occurred in the atmosphere around 400˜600° C. and accordingly,

Therefore, in case of actually using molybdenum or niobium on which the MoSi₂ coating is coated, a life span of the coating varies according to the condition under which it is used.

In case of isothermal oxidation which occurs in a high temperature oxidation atmosphere, silicon is diffused into molybdenum by the interdiffusion between molybdenum and MoSi₂ coating, and, accordingly, the MoSi₂ coating with excellent oxidation resistance is transformed into a Mo₅Si₃ coating without oxidation resistance, which can not be used as a surface protecting coating anymore. Therefore, in this case, the maximum life span of MoSi₂coating can be increased by increasing the thickness of it.

However, in case of cyclic oxidation occurring during the cyclic process of maintaining the above material in a high temperature oxidation atmosphere for a predetermined time and then cooling to a room temperature, when the temperature is raised to a high temperature, the micro crack in the coating is filled with silicon oxides formed from silicon within MoSi₂ coating (self-healing). On the other hand, when the coating is cooled to the room temperature, micro cracks are generated within the coating, due to the difference of thermal expansion coefficients between molybdenum or niobium and MoSi₂coating and silicon oxide layers.

As the number of cyclic oxidation between high temperature and room temperature increases, the size of the micro crack increases. When the size reaches to a critical point, the crack can not be filled any more, and molybdenum or niobium is directly exposed to oxygen which exists in the atmosphere, thus causing rapid oxidation.

In addition, the other problem is that, in the atmosphere around 400˜600° C., the MoSi₂ coating is rapidly oxidized into the powder types of molybdenum oxides (MoOₓ) and silicon oxides. As described above, this kind of oxidation is called as pest oxidation.

Particularly, volume expansion of about 250%, which is occurred when MoSi₂ is oxidized at a low temperature into molybdenum oxides and silicon oxides, causes generation of a pore and a micro crack, and disintegration of the MoSi₂ coating into a powder type. Accordingly, the MoSi₂ coating get lost low-temperature oxidation resistance.

Therefore, the reason that commercialization of molybdenum or niobium coated with MoSi₂ is difficult is that it has no cyclic oxidation resistance at a high temperature and no low-temperature oxidation resistance.

To improve cyclic oxidation resistance and low-temperature oxidation resistance of molybdenum or niobium coated with a MoSi₂ layer, two conventional methods have been developed.

Firstly, there is a method for improving cyclic oxidation resistance by filling the crack. In this method, when an alloy element is added to the MoSi₂ coating, a silicon oxide layer which is formed in a high-temperature oxidation atmosphere is alloyed to reduce a difference in thermal expansion coefficient between MoSi₂ coating and silicon oxide layer. Accordingly, at the room temperature, the peeling of oxide layer is restrained, and the viscosity of silicon oxide layer is reduced, and thus the oxide layer smoothly slips down into the micro crack.

As an example of the above method, the U.S. Pat. No. 2,865,088 disclosed that the cyclic oxidation resistance could be improved by the addition of chrome (Cr), boron(B) and the like. And the German Patent No. 1,960,836 has reported that the cyclic oxidation resistance was improved about five times in case of adding germanium (Ge).

Secondly, according to B. V. Cockeram et al. reported in the Oxidation of Metals, vol. 45 (1996) p. 77˜108, if sodium fluoride (NaF) is used as an activator in a manufacturing process of a MoSi₂ coating by a pack-siliconizing method, the sodium fluoride deposited on a surface of the coating layer has been known to be capable of improving low-temperature oxidation resistance of coating.

On the other hand, according to the disclosure of U.S. Pat. No. 5,472,487,when a properly mixed powder of MoSi₂, SiO₂, Si₃N₄, SiC and Mo₅Si₃ is coated by low-pressure plasma spraying on a niobium(Nb) metal having a thermal expansion coefficient of 7.9×10⁻⁶/° C., the thermal expansion coefficient of a composite coating becomes lower than the thermal expansion coefficient of the pure MoSi₂ coating, and the peeling of the surface protecting oxidation coating or the composite coating are not observed even if cyclic oxidation tests in which the metal is heated for an hour in an oxidation atmosphere of 2500° F. (about 1371° C.) and then is maintained for 55 minutes in room temperature, are cycled about 10 or more times.

However, the devices of the low-pressure plasma spraying method cost very much, a plurality of defects such as pores and the like exist in the coating, and the method is limited to be used in manufacturing of a thick coating having a thickness of several mms.

On the other hand, methods for reducing thermal expansion coefficient of MoSi₂ sintered composite improving pest oxidation are also reported.

The U.S. Pat. No. 6,288,000 discloses that a thermal expansion coefficient of MoSi₂—Si₃N₄ sintered composite which was manufactured by hot-isostatic pressing of powder mixture formed by adding MoSi₂ powder and Si₃N₄ powder having volume ratios of about 30% and 50% is lower than the thermal expansion coefficient of monolithic MoSi₂ and is similar as that of Mo at 1000˜1500° C.

The U.S. Pat. No. 5,429,997 disclosed that low-temperature oxidation resistance (in the atmosphere at 500° C.), high temperature isothermal oxidation resistance and cyclic oxidation resistance of MoSi₂—Si₃N₄ sintering which was manufactured by hot-isostatic pressing of powder mixture in which respectively Si₃N₄ powder having 30% and 45% of volume ratios is added is more excellent than in the case of monolithic MoSi₂.

FIG. 1 is a view showing a cross-sectional microstructure of MoSi₂—Si₃N₄ sintered composite manufactured by hot-isostatic pressing in the Materials Science and Engineering A261 (1999) p. 24-37 reported by Mohan G. Hebsur.

As shown in FIG. 1, the microstructure of the sintered composite is characterized in that the Si₃N₄ particles are irregularly formed in the MoSi₂ matrix. Therefore, the method was not efficient in preventing oxygen from diffusing through a MoSi₂ grain boundary into the layer by forming a Si₂ON₂ protection layer.

### SUMMARY OF THE INVENTION

Therefore, an object of the present invention is to provide a MoSi₂—Si₃N₄ composite coating and a manufacturing method thereof, capable of improving cyclic oxidation resistance and low-temperature oxidation resistance of base materials which are molybden, molybden alloy, molybden-coated niobium or molybden-coated niobium alloy, and improving high-temperature mechanical property of a coating.

To achieve these and other advantages and in accordance with the purpose of the present invention, as embodied and broadly described herein, there is provided a MoSi₂—Si₃N₄ composite coating which is coated on a surface of base materials which are molybden, molybden alloy, molybden-coated niobium or molybden-coated niobium alloy, and has a structure that Si₃N₄ particles are distributed along MoSi₂grain boundary of equiaxed grain.

Also, the present invention provides a manufacturing method of the MoSi₂—Si₃N₄ composite coating, including the steps of (a) forming a Mo₂N diffusion layer by vapor-depositing of nitrogen on the surface of the base material, (b) forming a MoSi₂—Si₃N₄ composite coating by vapor-depositing of silicon on the surface of the Mo₂N diffusion layer.

Also, the present invention provides a manufacturing method of the MoSi₂—Si₃N₄ composite coating, including the steps of (a) forming a MoSi₂ diffusion layer by vapor-depositing of silicon on the surface of the base material by the CVD method, (b) transforming the MoSi₂ diffusion layer into a Mo₅Si₃ diffusion layer by heating under a high-purity hydrogen or argon atmosphere, (c) forming a Mo₂N—Si₃N₄ composite diffusion layer by vapor-depositing of nitrogen on the surface of the Mo₅Si₃ diffusion layer by the CVD method, (d) forming a MoSi₂—Si₃N₄ composite coating by vapor-depositing of silicon on the surface of the Mo₂N—Si₃N₄ composite diffusion layer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a view showing a cross-sectional structure of MoSi₂—Si₃N₄ sintered composite manufactured by hot-isostatic pressing in the Materials Science and Engineering A261 (1999) p. 24-37 reported by Mohan G. Hebsur;

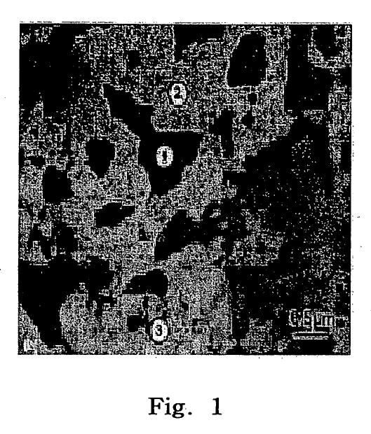

FIGS. 2a and 2b are views showing a cross-sectional structure and a surface structure of the MoSi₂ coating having a columnar structure by the conventional manufacturing methods, such as a CVD method, pack-siliconizing method, dipping method and the like;

FIGS. 3a and 3b are views showing a cross-sectional structure and a surface structure of a MoSi₂—Si₃N₄ composite coating which was formed by a manufacturing method of a first embodiment of the present invention; and

FIGS. 4a and 4b are views showing a cross-sectional structure and a surface structure of the MoSi₂—Si₃N₄ composite coating which was formed by a manufacturing method of a second embodiment of the present invention.

### DETAILED DESCRIPTION OF THE PREFERRED EMBODIMENTS

Reference will now be made in detail to the preferred embodiments of the present invention, examples of which are illustrated in the accompanying drawings.

Hereinafter, the MoSi₂—Si₃N₄ composite coating and the manufacturing method thereof in accordance with the present invention will be described.

The MoSi₂—Si₃N₄ composite coating in accordance with the present invention is coated on a surface of a base material made of molybden(Mo), molybden alloy, niobium coated by molybden, or niobium alloy coated by molybden, and thereby Si₃N₄ particles are distributed on an equiaxed MoSi₂ grain boundary.

Among MoSi₂—Si₃N₄ composite coatings, the microstructure of MoSi₂ has an equiaxed grain structure, and accordingly, transmission of fine cracks which can be occurred by thermal stress caused by a difference between thermal expansion coefficients of the base material and the coating can be restrained.

Among MoSi₂—Si₃N₄ composite coatings, Si₃N₄ is primarily formed on the MoSi₂ grain boundary by limitation of solubility on the MoSi₂ matrix.

Also, the thermal expansion coefficient of Si₃N₄ is about 3×10⁻⁶/° C. and accordingly, the thermal expansion coefficient (9.5×10⁻⁶/° C.) of pure MoSi₂ can be reduced to around that of the base material (Mo: 5.1×10⁻⁶/° C., Nb: 7.2×10⁻⁶/° C.), thus to improve cyclic oxidation resistance of the base material.

Also, the Si₃N₄ can be easily transformed into a Si₂ON₂ protection layer when oxygen is diffused into the grain through the grain boundary of MoSi₂ in an oxidation atmosphere, and prevent oxygen from diffusing inside through the MoSi₂ grain boundary, low-temperature oxidation resistance of the base material can be much better than that of the pure MoSi₂ coating. Such micro-structural property of the MoSi₂—Si₃N₄ composite coating can efficiently control oxygen diffusion through the grain boundary of MoSi₂ with relatively smaller amount of Si₃N₄ than in the case of the MoSi₂—Si₃N₄sintered composite.

Also, the Si₃N₄ particles control growth of the MoSi₂ grain, and prevents degradation of the mechanical property of the coating by grain coarsening.

The manufacturing method of the MoSi₂—Si₃N₄ composite coating in accordance with the present invention includes the steps of (a) forming a Mo₂N diffusion layer by vapor-depositing of nitrogen on the surface of the base material, (b) forming a MoSi₂—Si₃N₄ composite coating by vapor-depositing of silicon on the surface of the Mo₂N diffusion layer.

In the above step (a), nitrogen is vapor-deposited on the surface of the base material which is maintained in a high-temperature hydrogen atmosphere by the CVD method, and nitrogen (N₂) or ammonia (NH₃) can be used when depositing nitrogen by the CVD method.

In this case, nitrogen which is deposited on the surface of the base material chemically react with the base material and forms a molybden nitride (Mo₂N) diffusion layer. As a deposition time passes, nitrogen which is deposited on the surfaces of the base material moves to a Mo₂N/Mo interface through the Mo₂N layer and reacts with new molybden. Accordingly, the Mo₂N layer is continuously generated and the thickness of the Mo₂N layer increases in proportion to a square root of the deposition time. The thickness of the Mo₂N layer varies according to the deposition temperature and time.

The growth rate of the Mo₂N layer which was formed on the Mo base material at 1100° C. by chemical deposition of nitrogen can be disclosed as following Formula [1].
(thickness of Mo₂N layer)² (cm²)=7.82×10⁻¹⁰×time (sec) [1]

In the above step (b), after manufacturing the Mo₂N layer having a predetermined thickness on the surface of the base material, silicon is vapor-deposited for a predetermined time using SiCl₄, SiH₂Cl₂, SiH₃Cl or SiH₄ under the condition that the deposition temperature is maintained as it is.

In this case, a pack-siliconizing method which uses pack-siliconizing processing powder comprised of (1-70)wt % of Si, (1-10)wt % of NaF and (20-98)wt % of Al₂O₃ can be used for vapor-depositing of silicon.

When the deposited silicon is diffused into Mo₂N, MoSi₂ and Si₃N₄ are formed by a displacement reaction as shown in following Formula [2].
4Mo₂N+19Si→8MoSi₂+Si₃N₄ [2]

Since the nitrogen solubility limit in the MoSi₂, the Si₃N₄ particles which are formed by Formula (b) are formed in the MoSi₂ grain boundary.

Silicon which was deposited on the surface of the base material continuously moves into through the MoSi₂—Si₃N₄ composite coating and reacts with the Mo₂N diffusion layer. Therefore, new grains of MoSi₂ and Si₃N₄ are formed to enable manufacturing of the MoSi₂—Si₃N₄ composite coating.

Since the thickness of the MoSi₂—Si₃N₄ composite coating increases in proportion to the square root of the vapor-deposition time of silicon, the deposition temperature and time for manufacturing a composite coating having a predetermined thickness can be calculated through reaction kinetics.

The growth rate of the MoSi₂—Si₃N₄composite coating which was formed on the Mo₂N layer at 1100° C. by vapor-deposition of Si can be disclosed as following Formula [3].
(thickness of MoSi₂+Si₃N₄ composite coating)²(cm²)=2.78×10⁻⁹×time (sec) [3]

On the other hand, as the other manufacturing method of the MoSi₂—Si₃N₄ composite coating in accordance with the present invention, the manufacturing method of the MoSi₂—Si₃N₄ composite coating includes the steps of (a) forming a MoSi₂ diffusion layer by vapor-depositing of silicon on the surface of the base material by the CVD method, (b) transforming the MoSi₂ diffusion layer into a Mo₅Si₃ diffusion layer by heating under a high-purity hydrogen or argon atmosphere, (c) forming a Mo₂N—Si₃N₄ composite diffusion layer by vapor-depositing of nitrogen on the surface of the Mo₅Si₃ diffusion layer by the CVD method, (d) forming a MoSi₂—Si₃N₄ composite coating by vapor-depositing of silicon on the surface of the Mo₂N—Si₃N₄ composite diffusion layer.

In the above step (a), silicon is vapor-deposited on the surface of the base material which is maintained in a high-temperature hydrogen atmosphere, by the CVD method for a predetermined time using SiCl₄, SiH₂Cl₂, SiH₃Cl or SiH₄.

In this case, as the method for vapor-depositing of silicon, a pack-siliconizing method which uses the pack-siliconizing processing powder comprised of (1-70)wt % of Si, (1-10)wt % of NaF, and (20-98)wt % of Al₂O₃ can be used.

The MoSi₂ diffusion layer is manufactured on the surfaces of the base material by diffusing the reaction of silicon into the base material. In this case, the deposited silicon moves to the MoSi₂/Mo interface through the MoSi₂ diffusion layer and reacts with new molybden, thus to continuously generate the MoSi₂ layer. Therefore, the thickness of the MoSi₂ diffusion layer increases in proportion to the square root of the deposition time.

Therefore, the deposition temperature and time for manufacturing the MoSi₂ diffusion layer having a predetermined thickness can be calculated through reaction kinetics.

The growth rate of the MoSi₂ diffusion layer which was formed on the Mo layer at 1100° C. by vapor-deposition of Si can be disclosed as following Formula [4].
(thickness of MoSi₂ diffusion layer)² (cm²)=1.88×10⁻⁹×time (sec) [4]

In the above step (b), the MoSi₂ diffusion layer is transformed to the Mo₅Si₃ diffusion layer when the MoSi₂ diffusion layer is heated under a high-purity hydrogen or argon atmosphere after manufacturing the layer having a predetermined thickness.

In this case, temperature and time for completely transforming the MoSi₂ layer having a predetermined thickness into the Mo₅Si₃ layer can be calculated through reaction kinetics since the rate that the MoSi₂ is transformed into the Mo₅Si₃ depends upon a high diffusion rate of Si through the Mo₅Si₃ layer.

The transformation rate of the MoSi₂ diffusion layer into the Mo layer at 1200° C. can be disclosed following Formula [5].
(thickness of Mo₅Si₃ diffusion layer)² (cm²)=6.02×10⁻¹¹×time (sec) [5]

In the above step (c), after the MoSi₂ diffusion layer is completely transformed to the Mo₅Si₃ diffusion layer, the supply of hydrogen is stopped again, and nitrogen is vapor-deposited on the surface of the Mo₅Si₃ diffusion layer by the CVD method using nitrogen or ammonia gas for a predetermined time.

In this case, when the deposited nitrogen is diffused into the Mo₅Si₃ diffusion layer, the Mo₂N and Si₃N₄ are formed by a displacement reaction as in Formula [6].
2Mo₅Si₃+13N→5Mo₂N+2Si₃N₄ [6]

As nitrogen which is deposited on the surface of Mo₂N—Si₃N₄ continuously moves inside through the Mo₂N—Si₃N₄ composite diffusion layer, and reacts with the Mo₅Si₃ diffusion layer, forming new Mo₂N and Si₃N₄ grains according to Formula [6], it is possible to manufacture the Mo₂N—Si₃N₄composite diffusion layer.

Since thickness of the Mo₂N—Si₃N₄ composite diffusion layer increases in proportion to the square root of vapor-deposition time of nitrogen, deposition temperature and time for manufacturing a composite diffusion layer having a predetermined thickness can also be calculated through reaction kinetics.

The growth rate of the Mo₂N—Si₃N₄ composite diffusion layer which was formed on the Mo₅Si₃ base material at 1100° C. by chemical deposition of nitrogen can be disclosed as following Formula [7].
(thickness of Mo₂N—Si₃N₄ composite diffusion layer)² (cm²)7.09×⁻¹⁰×time (sec) [7]

In the above step (d), silicon is vapor-deposited by the CVD method for a predetermined time using SiCl₄, SiH₂Cl₂, SiH₃Cl or SiH₄ after manufacturing the Mo₂N—Si₃N₄ composite diffusion layer having a predetermined thickness.

In this case, as the method for vapor-depositing of silicon, a pack-siliconizing method which uses the pack-siliconizing processing powder comprised of (1-70)wt % of Si,(1-10)wt % of NaF, and (20-98)wt % of Al₂O₃ can be used.

In this case, when the deposited silicon is diffused into the Mo₂N—Si₃N₄ composite diffusion layer, the MoSi₂ and the Si₃N₄ are formed by a displacement reaction as in Formula [2], thus to manufacture the MoSi₂—Si₃N₄ composite coating on the surface of molybden.

Since the thickness of the MoSi₂—Si₃N₄ composite coating increases in proportion to the square root of vapor-deposition time of silicon, deposition temperature and time for manufacturing a composite coating having a predetermined thickness can also be calculated through reaction kinetics.

The growth rate of the MoSi₂—Si₃N₄ composite coating which was formed on the Mo₂N—Si₃N₄ composite diffusion layer at 1100° C. by vapor-deposition of Si can be disclosed as following Formula [8].
(thickness of MoSi₂+Si₃N₄ composite coating)² (cm²)=1.03×10−8×time (sec) [8]

On the other hand, comparison of the two manufacturing methods of the MoSi₂—Si₃N₄ composite coating (method 1 and method 2) will be described as follows.

In case the MoSi₂—Si₃N₄ composite coating is manufactured by the reaction of Formula [9] according to the method 1, the theoretical volume ratio of Si₃N₄ grain is calculated using the volume per a molecule of MoSi₂ (24.4 cm³/mol) and Si₃N₄ (44.07 cm³/mol), the ratio can be disclosed as follows.
4Mo₂N+19Si→8MoSi₂+Si₃N₄ [9]

Si₃N₄ vol %=(44.07)/(44.07+8∴24.4)×100=18.4%, and the volume ratio of Si₃N₄ which was experimentally formed is about 12.9˜17.7%.

However, when nitrogen is chemically deposited on Mo₅Si₃ according to the method 2, Mo₂N and Si₃N₄ are formed by the reaction of following Formula [10].
8Mo₅Si₃+52N→20Mo₂N+8Si₃N₄ [10]

When silicon is chemically deposited, Mo₂N and Si forms MoSi₂ and Si₃N₄ by the reaction of following Formula [11].
20Mo₂N+95Si→40MoSi₂+5Si₃N₄ [11]

Therefore, the total generation reaction of the MoSi₂—Si₃N₄ composite coating which is formed by depositing nitrogen on the Mo₅Si₃ can be disclosed as in Formula [12].
8Mo₅Si₃+52N+95Si→40MoSi₂+13Si₃N₄ [12]

Therefore, in case the composite coating is manufactured using the Mo₅Si₃, the theoretical volume ratio of the Si₃N₄ amounts to Si₃N₄ vol %=(13×44.07)/(13×44.07+40×24.4)×100=37%.

However, the volume ratio which was experimentally measured is about 30˜33%. Therefore, in case the composite coating is manufactured using the Mo₅Si₃, the volume ratio of the Si₃N₄ becomes about 30˜33%. The thermal expansion coefficient of molybden and the composite coating become almost identical, and as the result, cracks are not formed in the composite coating.

### EXAMPLE 1

In Example 1, the MoSi₂—Si₃N₄ composite coating was manufactured by the method 1, and the purity of molybden used in Example 1 is 99.95%. The purity of niobium is 99.9% and each of the material is formed as a plate of 10 mm×10 mm×1 mm size.

After grinding molybden and niobium test pieces successively using SiC papers and 1 μm diamond paste, the above materials are washed in the supersonic washer with acetone, alcohol and distilled water respectively for 10 minutes to remove organic material which can exist on the surface. The resultant material was dried and was used as a base material for coating.

Particularly, in case of the niobium test piece, the test piece which was formed by depositing molybden on the surface of the pre-processed niobium in the thickness of about 30 μm using the DC magnetron sputtering device was used as the base material of the Example. During deposition, the pressure of argon inside the reaction chamber was maintained as about 1˜20 m torr.

Nitrogen and silicon are inserted in a quartz reaction tube for chemical vapor-deposition on the surface of the pre-processed molybden and niobium, and oxygen in the reaction tube is removed by introducing high-purity argon gas (99.9999%). As introducing high-purity hydrogen (99.9999%) or high-purity argon at a rate of 100˜2,000 cm/min, the materials are heated to 800˜1400° C. at a heating rate of 5˜20° C./min, and metallic oxides which can exist in the metal surfaces of the metals are reduced. To stabilize the deposition temperature, the temperature was maintained for about 10˜20 minutes and the supply of hydrogen was stopped. Then, nitrogen is deposited on the metallic surfaces for about 10 minutes˜20 hours supplying ammonia gas at a flow rate of 3˜2,000 cm/min

Nitrogen deposited on the surface of the base material reacts chemically with molybden and forms a compound layer of the Mo₂N composition. As the deposition time passes, nitrogen deposited on the surface of the metals moves to the Mo₂N/Mo interface through the Mo₂N layer and continuously generates Mo₂N by reacting with new molybden. The Mo₂N layer grows in proportion to the square root of the deposition time.

Therefore, the deposition temperature and time for manufacturing the Mo₂N layer having a predetermined thickness can be calculated through reaction kinetics. As an example, when nitrogen is chemically vapor-deposited at the deposition temperature of 1100° C. for about 2 hours, Mo₂N diffusion layer having a thickness of about 24 μm grows on the molybden metal surface.

After manufacturing the Mo₂N diffusion layer having a predetermined thickness, the supply of ammonia gas is stopped, and the ammonia gas which is remained inside the reaction tube by supplying hydrogen to the reaction tube for 1˜30 minutes at a flow rate of 30˜3,000 cm/min. Silicon is chemically vapor-deposited on the surface of the Mo₂N diffusion layer for 30 minutes˜30 hours while supplying silicon tetrachloride gas and hydrogen to the reaction tube to have the total flow rate of the two gases as about 30˜4,000 cm/min and the flow rate ratio as about 0.005˜0.5.

The deposited silicon forms the MoSi₂ and Si₃N₄ by displacement reaction with the Mo₂N. As the deposition time passes, the deposited silicon continuously moves into through the MoSi₂—Si₃N₄ composite coating, and reacts with the Mo₂N diffusion layer. Accordingly new MoSi₂ grain and Si₃N₄ grain are formed, and the MoSi₂—Si₃N₄ composite coating can be formed.

Since the thickness of the MoSi₂—Si₃N₄ composite coating increases in proportion to the square root of the vapor-deposition time, the deposition temperature and time for manufacturing the composite coating of a predetermined thickness can be calculated through reaction kinetics. As an example, a MoSi₂—Si₃N₄ composite coating having a thickness of 70 μm which is excellent in oxidation resistance and corrosion resistance can be formed on the surfaces of molybden and niobium by chemically vapor-depositing silicon on the surface of the Mo₂N diffusion layer for 5 hours at the deposition temperature of 1100° C. and by having it reaction-diffused into the Mo₂N.

After forming the composite coating, high-purity hydrogen gas or high-purity argon gas are flowed at a flow rate of 100˜2,000 cm/min and the coating was furnace-cooled to the room temperature.

On the other hand, high-purity solutions, which are used in the field of semiconductor, were used as hydrogen and silicon tetrachloride gases in Example 1 of the present invention. Particularly, in the present invention, since the vaporization temperature of the silicon tetrachloride gas is about 54° C., silicon was supplied to the reaction tube by bubbling using hydrogen gas after injecting the silicon tetrachloride solution into a bubbler which was maintained at constant temperature of 0˜30° C. In the present invention, the chemical vapor-deposition was performed in a tube furnace in which a reaction tube manufactured with a quartz tube having an inner diameter of 20 mm.

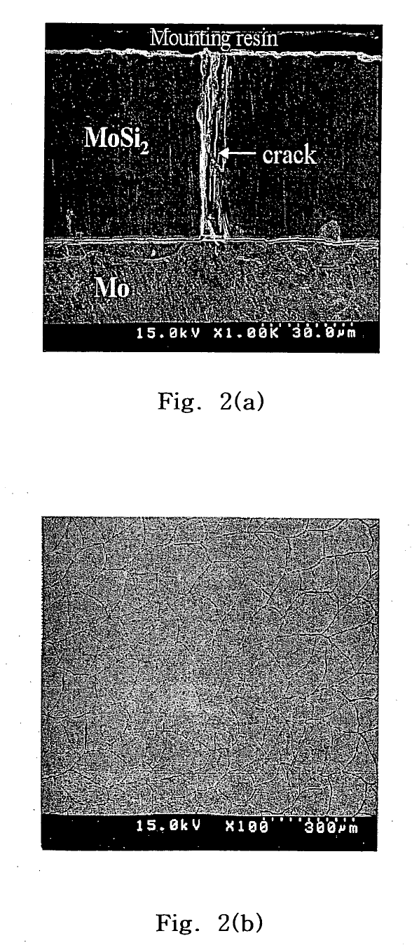

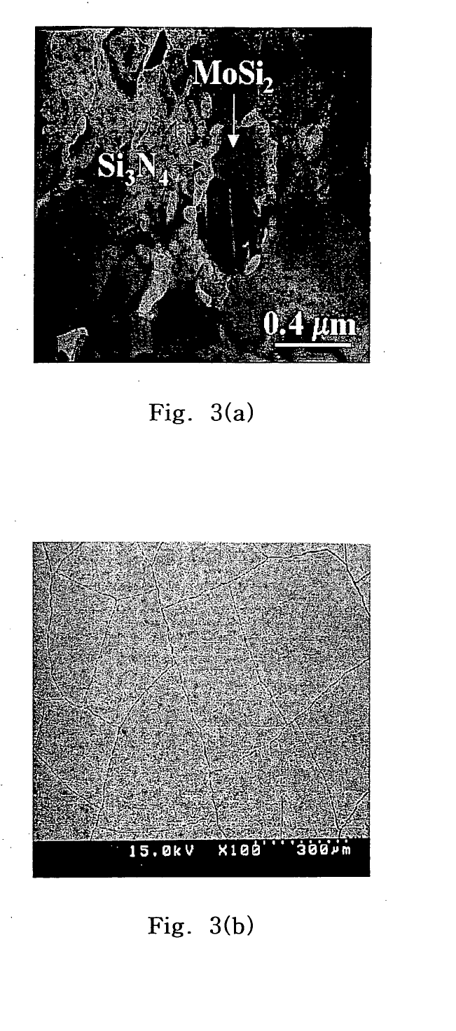

FIGS. 2A and 2B are views showing a cross-sectional structure and a surface structure of the MoSi₂ coating having a columnar structure which was manufactured by the CVD method, pack-siliconizing method, dipping method and the like respectively which are conventional methods for processing the surface to process the surface of the base material, FIGS. 3A and 3B are views showing a cross-sectional structure and a surface structure of the MoSi₂—Si₃N₄ composite coating which was formed by the manufacturing method of the MoSi₂—Si₃N₄ composite coating in accordance with the present invention.

FIG. 3A is a view showing a result that the sectional microstructure of the MoSi₂—Si₃N₄ composite coating manufactured by the method 1 of Example 1 was observed with a transmission electron microscope (TEM), and FIG. 3B is a view showing a result that the surface structure of the composite coating was observed with a back scattering SEM.

On the other hand, the MoSi₂ coating which was manufactured by depositing silicon on the molybden base material by the CVD method which is the conventional surface-processing method and the MoSi₂—Si₃N₄ composite coating manufactured by the method 1 of Example 1 in accordance with the present invention will be compared with each other.

As shown in FIGS. 3A and 3B, ultra micro Si₃N₄ is precipitated on the equiaxed grain MoSi₂ grain boundary in the MoSi₂—Si₃N₄ composite coating manufactured by the method 1 in Example 1 in accordance with the present invention. The average grain size of the equiaxed grain MoSi₂ calculated by an image analyzer is about 0.5˜0.3 μm. The average size and volume ratio of the Si₃N₄ precipitates were about 80˜120 nm and 12.9˜17.7%.

Also, as the Si₃N₄ particles are mainly formed in the MoSi₂ grain boundary, growth of the MoSi₂ grains is restrained, and accordingly, manufacturing of the equiaxed grain MoSi₂ coating having an average grain size of about 0.5˜0.3 μm is enabled.

On the other hand, the MoSi₂ coating which was manufactured by depositing silicon by the CVD method which is the conventional surface-processing method has a columnar structure as shown in FIGS. 2A and 2B.

Particularly, as shown in FIGS. 2b and 3b, in the MoSi₂—Si₃N₄ composite coating which was manufactured by the method 1 in Example 1 in accordance with the present invention, when the surface of the coating is observed with a back scattered SEM, was calculated. As the result, the number of the cracks in a unit length was about 50 ea/cm showing 64% of decrease from 140 ea/cm for the conventional coating.

Since the thermal expansion coefficient of the MoSi₂-(12.9˜17.7 vol. %) Si₃N₄ composite coating, is higher than that of Mo which is the base material, a tensile stress is at work in the composite coating in case of cooling from the deposition temperature to the room temperature. Therefore, the crack could not be completely removed.

### EXAMPLE 2

In Example 2, the MoSi₂—Si₃N₄ composite coating was manufactured by the method 1 among the manufacturing methods of the MoSi₂—Si₃N₄ composite coating.

As in Example 1, after manufacturing a Mo₂N diffusion layer having a thickness of about 20 μm in the surface of molybden and niobium metals, the resultant material is furnace-cooled to the room temperature while introducing high-purity hydrogen or high-purity argon at a flow rate of 100˜2,000 cm/min.

On the other hand, contrary to Example 1, molybden and niobium metals coated by the Mo₂N diffusion layer having a predetermined thickness are embedded in a mixture powder in a composition of (1˜70)wt % of Si, (1˜10) wt % of NaF, and (20˜98)wt % of Al₂O₃ and then inserted in a reaction tube for pack-siliconizing.

By introducing high-purity argon gas, oxygen in the reaction tube was removed, and the reaction tube is heated to 800˜1400° C. at a heating rate of 5˜20° C./min while introducing high-purity hydrogen or high-purity argon at a flow rate of 100˜2,000 cm/min. The deposited silicon reacts with Mo₂N layer on the metal surface by maintaining the temperature for 30 minutes˜30 hours.

After manufacturing the MoSi₂—Si₃N₄ composite coating on the metal surface, the metal is furnace-cooled to the room temperature while introducing high-purity hydrogen or high-purity argon at a flow rate of 100˜2,000 cm/min.

Since the thickness of the MoSi₂—Si₃N₄ composite coating which was manufactured by the pack-siliconizing method increases in proportion to the square root of the silicon deposition time as in the chemical deposition, the deposition temperature and time for manufacturing a composite coating having a specific thickness can be expected through reaction kinetics.

A powder, which was manufactured by mixing 30 g of the powder comprised of (1˜70)wt % of Si, (1˜10)wt % of NaF, and (20˜98)wt % of Al₂O₃ for 24 hours using a mixer which can perform rotation and upper and lower movements simultaneously, was used as the pack-siliconizing processing powder. The used silicon powder has a purity of 99.5% and an average grain size of 325 mesh, a NaF reagent was used as an activator, and high-purity alumina of an average size of 325 mesh was used as a filler.

Pack-siliconizing which is performed at lower than 1100° C. was performed in a tube furnace in which the reaction tube having the inner diameter of 60 mm, which was manufactured with an inconel 600, is mounted, and in case of higher than 1200° C., a high-purity alumina tube was used. The mixed pack-siliconizing processing powder was filled in an alumina crucible of 40 cc, molybden or niobium metal coated by the Mo₂N diffusion layer is embedded at the center, and then the tube was enclosed by the alumina cover.

### EXAMPLE 3

In Example 3 the MoSi₂—Si₃N₄ composite coating was manufactured by the method 2 among the manufacturing methods of the MoSi₂—Si₃N₄ composite coating in accordance with the present invention.

As in Example 1, after heating the molybden and niobium metals to the deposition temperature, and fixing a total flow rate of two gases to become about 30˜4,000 cm/min while a flow rate ratio of silicon tetrachloride gas and hydrogen becomes about 0.005˜0.3, silicon is chemically vapor-deposited on the metal surface for 10 minutes˜30 hours by supplying the gases to the reaction tube. Accordingly, the MoSi₂ diffusion layer is manufactured on the surface of the molybden and niobium metals as silicon diffuses into Mo.

In this case, the deposited silicon moves to a MoSi₂/Mo interface through the MoSi₂ diffusion layer, reacts with new molybden, thus to continuously generate the MoSi₂ layer. Therefore, since the thickness of the MoSi₂ diffusion layer increases in proportion to the square root of the silicon deposition time, the deposition temperature and time for manufacturing a MoSi₂ diffusion layer having a specific thickness can be expected through reaction kinetics. As an example, when silicon is chemically vapor-deposited at the deposition temperature of 1100° C. for 30 minutes, the MoSi₂ diffusion layer having a thickness of about 18 μm grows on the surface made of molybden or niobium metals.

After manufacturing the MoSi₂ diffusion layer having a thickness of about 18 μm, supply of silicon tetrachloride gas is stopped, and then the layer is heated to 1200° C. at a heating rate of 5˜20° C./min while supplying hydrogen to the reaction tube at a flow rate of 100˜2,000 cm/min. When the temperature is maintained for 70 hours, the MoSi₂ diffusion layer having a thickness of about 18 μm is transformed to the Mo₅Si₃ diffusion layer having a thickness of about 34 μm.

In this case, the MoSi₂ diffusion layer can be transformed to the Mo₅Si₃ diffusion layer in a hydrogen atmosphere at 1100° C., but since it takes much time to transform, it is desirable that the diffusion heating temperature is raised to 1200° C. In case the reaction tube is alumina, since the temperature of the material can be raised to a high temperature, heating time for transforming the MoSi₂ diffusion layer into the Mo₅Si₃ diffusion layer can be substantially reduced.

After the MoSi₂ diffusion layer is completely transformed into the Mo₅Si₃ diffusion layer, the temperature is decreased to the deposition temperature of 1100° C. at a cooling rate of 5˜20° C/min again.

Next, nitrogen is chemically vapor-deposited on the surface of the Mo₅Si₃ diffusion layer for 10 hours while supplying ammonia gas into the reaction tube at a flow rate of 3˜2,000 cm/min after stopping the supply of hydrogen, and accordingly, a Mo₂N—Si₃N₄ diffusion layer having a thickness of about 50 μm is manufactured on the surface of molybden or niobium metals.

After removing ammonia gas which is remained inside the reaction tube by supplying hydrogen into the reaction tube at a flow rate of 30˜3,000 cm/min for 1˜30 minutes, silicon is chemically vapor-deposited on the metal surface for about an hour and when silicon is diffused into of the Mo₂N—Si₃N₄ diffusion layer, the silicon reacts with the Mo₂N. Accordingly, the MoSi₂ and Si₃N₄ are formed, and a MoSi₂—Si₃N₄ composite coating having a thickness of 60 μm which is excellent in oxidation resistance and corrosion resistance was manufactured on the surface of molybden and niobium metals.

In case of Example 3, since the thickness of the manufactured MoSi₂—Si₃N₄ composite coating increases in proportion to the square root of the silicon deposition time, the deposition temperature and time for manufacturing a composite coating having a predetermined thickness can be calculated through reaction kinetics.

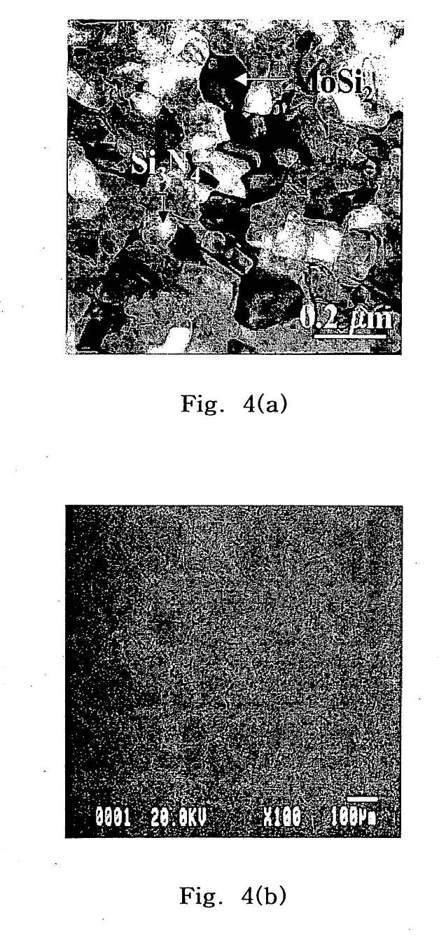

FIG. 4A shows a result that the cross-sectional microstructure of the MoSi₂—Si₃N₄ composite coating which was manufactured by the above method is observed by a TEM. FIG. 4B is a view showing a result that the surface of the composite coating is observed by a back scattered scanning electron microscope (SEM) and shows that super-micro Si₃N₄ is precipitated on the equiaxed MoSi₂ grain boundary. The average grain size which is calculated with an image analyzer is about 90 nm and the volume ratio and the average size of the Si₃N₄ particles were about 60 nm and 30˜33%.

Contrary to a surface structure (FIG. 2B) of the MoSi₂ coating manufactured by depositing silicon on the molybden base material by the chemical vapor-deposition method, and a surface structure (FIG. 3B) of the MoSi₂—Si₃N₄ composite coating which is manufactured by the method of Example 1, in case of the surface structure (FIG. 4B) of the MoSi₂—Si₃N₄ composite coating which was manufactured by the method of Example 3, the cracks were not observed on the surface of the coating.

### EXAMPLE 4

The Mo₅Si₃ coating having a thickness of about 35 μm is manufactured on the surface of molybden and niobium metals by a method which is identical as Example 3, and the coating is furnace-cooled to the room temperature while introducing high-purity hydrogen or high-purity argon at a flow rate of 100˜2,000 cm/min.

The MoSi₂—Si₃N₄ composite coating which is excellent in oxidation resistance and corrosion resistance is manufactured on the surface of molybden and niobium metals by vapor-depositing silicon with the pack-siliconizing method identical as Example 2, and the coating is furnace-cooled to the room temperature while flowing high-purity hydrogen or high-purity argon at a flow rate of 100˜2,000 cm/min.

Since the thickness of the MoSi₂—Si₃N₄ composite coating which was manufactured according to Example 4 also increases in proportion to the square root of the silicon deposition time, the deposition temperature and time for manufacturing the composite coating having a predetermined thickness can be calculated through reaction kinetics.

A cyclic oxidation resistance and low-temperature oxidation resistance are compared between a simple MoSi₂ coating and a MoSi₂—Si₃N₄ composite coating as follows.

### COMPARISON EXAMPLE 1

Cyclic oxidation resistance tests were performed by using molybden coated by a MoSi₂ layer having a thickness of 50 μm and a molybden test piece including a MoSi₂—Si₃N₄ composite coating having a thickness of 60 μm which was manufactured according to Example 3.

In the cyclic oxidation resistance test, the two test pieces are put on the alumina boat, they are inserted in the heating unit using an automatic feeding apparatus in a rotary kiln which was pre-heated to 1300° C. in the air, and the material is heated for 55 minutes and air-cooled for 30 minutes. The above process was tested as 1 time, and the cyclic oxidation resistance was estimated according to weight change per a unit surface area for every predetermined number of time using an electronic scale having a resolving power of 10⁻⁵ g.

As the result of the estimation, in case of molybden coated by the MoSi₂ layer, about 20 mg/cm² of weight loss was observed after about 20 times of cyclic oxidation tests, but in case of the molybden test piece on which the MoSi₂—Si₃N₄ composite coating is formed, about 0.35 mg/cm² of weight-increase was observed after about 300 times of the cyclic oxidation tests.

Therefore, in case of molybden coated by the MoSi₂ layer, oxygen which has easily diffused through cracks formed in a coating after a very short cyclic oxidation test reacts with molybdenum to be volatilized into MoO₃. Accordingly, rapid weight loss is observed, but in case of molybdenum on which the MoSi₂—Si₃N₄ composite coating is formed, since oxygen can not diffused into the coating even after about 300 times of cyclic oxidation tests, oxidation is proceeded only on a surface of a composite coating which is exposed in the air, a small amount of weight increase is observed.

### COMPARISON EXAMPLE 2

A low-temperature oxidation resistant test was performed using molybdenum on which the MoSi₂ layer having a thickness of 50 μm is coated, and a molybdenum test piece on which the MoSi₂—Si₃N₄ composite coating having a thickness of 60 μm is formed.

In the low-temperature oxidation resistant test, the two test pieces are put on the alumina boat, they are inserted in the heating unit using an automatic feeding apparatus in a rotary kiln which was pre-heated to 500° C. in the air, and the material is heated for 55 minutes and air-cooled for 5 minutes. The above process was tested as 1 time, and the low-temperature oxidation resistance was estimated according to the degree of powderization by observing the surface of the test piece which pass the low-temperature oxidation using an optical microscope.

In case of molybden coated by the MoSi₂ layer, it could be observed that a amount of MoO₃ and SiO₄ powders which are products of the low-temperature oxidation reaction are formed on the surface of the coating after about 50 times of low-temperature oxidation tests. However, in case of the molybden test piece on which the MoSi₂—Si₃N₄ composite coating is formed, the product of the low-temperature is hardly observed on the surface of the coating even after about 1,000 times of low-temperature oxidation tests.

The present invention can provide a MoSi₂—Si₃N₄ composite coating having a new structure by forming the Si₃N₄ particles in the MoSi₂ grain boundary which indicates a microstructure in the shape of the equiaxed grain in the surface of the base material using the chemical vapor-deposition method and the pack-siliconizing method among diffusion methods which have excellent advantages of simplicity, economic efficiency, and an excellent interface-binding force of the base material and the coating.

The MoSi₂—Si₃N₄ composite coating can reduce the difference of thermal expansion coefficients between the composite coating and the base material, and completely restrain formation of the fine cracks inside the composite coating, thus to improve cyclic oxidation resistance. The present invention can also restrain diffusion of oxygen through the grain boundary due to the Si₃N₄ particles formed in the MoSi₂ grain boundary, and the low-temperature oxidation resistance can be also improved, thus to improve the mechanical property of the coating by grain refining (restraining of transmission of the fine crack by thermal stress).

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

1. (canceled)

2. A manufacturing method of a MoSi₂—Si₃N₄ composite coating, comprising the steps of:
forming a Mo₂N diffusion layer by vapor-depositing of nitrogen on the surface of the base material; and
forming a MoSi₂—Si₃N₄ composite coating by vapor-depositing of silicon on the surface of the Mo₂N diffusion layer.

3. The method of claim 2, wherein the method for vapor-depositing of nitrogen on the surface of the base material of the step (a) is a CVD method using nitrogen (N₂) or ammonia (NH₃).

4. The method of claim 2, where the method for vapor-depositing of silicon on a surface of the Mo₂N diffusion layer in the step (b) is a CVD method using SiCl₄, SiH₂Cl₂, SiH₃Cl or SiH₄.

5. The method of claim 2, where the method for vapor-depositing of silicon on a surface of the Mo₂N diffusion layer in the step (b) is a pack-siliconizing method using pack-siliconizing processing powder having a composition of (1-70)wt % of Si, (1-10)wt % of NaF and (20-98)wt % of Al₂O₃.

6. A manufacturing method of a MoSi₂—Si₃N₄ composite coating which is coated on molybden (Mo), molybden alloy, niobium coated by molybden, or niobium alloy coated by niobium or molybden, comprising the steps of:
forming a MoSi₂ diffusion layer by vapor-depositing of silicon on a surface of a base material by the CVD method;
transforming the MoSi₂ diffusion layer into a Mo₅Si₃ diffusion layer by heating under a high-purity hydrogen or argon atmosphere;
forming a Mo₂N—Si₃N₄ composite diffusion layer by vapor-depositing of nitrogen on the surface of the Mo₅Si₃ diffusion layer by the CVD method; and
forming a MoSi₂—Si₃N₄ composite coating by vapor-depositing of silicon on the surface of the Mo₂N—Si₃N₄ composite diffusion layer.

7. The method of claim 6, wherein the method for vapor-depositing of nitrogen on a surface of the Mo₅Si₃ diffusion layer in the step (c) is a CVD method using nitrogen(N₂) or ammonia (NH₃).

8. The method of claim 6, wherein the method for vapor-depositing of silicon on the surface of the base material in the step (a) is a CVD method using SiCl₄, SiH₂Cl₂, SiH₃Cl or SiH₄.

9. The method of claim 8, wherein the method for vapor-depositing of nitrogen on the surface of the Mo₅Si₃ diffusion layer in the step (c) is a CVD method using nitrogen(N₂) or ammonia (NH₃).

10. The method of claim 6, wherein the method for vapor-depositing of silicon on a surface of the base material in the step (a) is a pack-siliconizing method using pack-siliconizing processing powder having a composition of (1-70)wt % of Si, (1-10)wt % of NaF and (20-98)wt % of Al₂O₃.

11. The method of claim 10, wherein the method for vapor-depositing of nitrogen on the surface of the Mo₅Si₃ diffusion layer in the step (c) is a CVD method using nitrogen(N₂) or ammonia (NH₃).

12. The method of claim 6, wherein the method for vapor-depositing of silicon on the surface of the Mo₂N—Si₃N₄ composite diffusion layer in the step (d) is a CVD method using SiCl₄, SiH₂Cl₂, SiH₃Cl or SiH₄.

13. The method of claim 6, wherein the method for vapor-depositing of silicon on the surface of the composite diffusion layer in the step (d) is a pack-siliconizing method using pack-siliconizing processing powder having a composition of (1-70)wt % of Si, (1-10)wt % of NaF and (20-98)wt % of Al₂O₃.

14-15. (canceled)
